(19) United States
(12) Patent Application Publication
(10) Pub. No.: US 2026/0190731 A1
(43) Pub. Date: Jul. 2, 2026

(54) ORGANIC LIGHT EMITTING DISPLAY APPARATUS

(71) Applicant: LG Display Co., Ltd., Seoul (KR)

(72) Inventors: Binn KIM, Paju-si (KR); BuYeol LEE, Paju-si (KR)

(73) Assignee: LG Display Co., Ltd., Seoul (KR)

(21) Appl. No.: 19/403,698

(22) Filed: Nov. 28, 2025

(30) Foreign Application Priority Data
Dec. 26, 2024 (KR) 10-2024-0197544

(51) Int. Cl. H10K 59/35; H10K 59/131

(52) U.S. Cl. CPC H10K 59/352; H10K 59/131; H10K 59/351

(57) ABSTRACT

A display apparatus can include a first pixel having three sub pixels configured to display different colors, and a second pixel adjacent to the first pixel and including three sub pixels configured to display different colors. One sub pixel among the three sub pixels of the second pixel is configured to display a color different from the colors displayed by the three sub pixels of the first pixel.

### CROSS-REFERENCE TO RELATED APPLICATION

This application claims priority to Korean Patent Application No. 10-2024-0197544, filed in the Republic of Korea on December 26, 2024, which is hereby expressly incorporated by reference in its entirety.

### BACKGROUND

### Field of Technology

The present disclosure relates to a display apparatus.

### Discussion of the Related Art

As the information society evolves, demand for display apparatuses for displaying images is increasing in various forms. Accordingly, various display apparatuses, such as liquid crystal displays (LCD), plasma display panels (PDP), and organic light emitting displays, are now being utilized.

Among the display apparatuses, organic light emitting diodes (OLED) in the organic light emitting displays are self-luminous and offer superior viewing angles and contrast ratios compared to liquid crystal displays (LCD). Furthermore, the organic light emitting displays do not require a separate backlight, allowing for lightweight and thin designs and lower power consumption. Furthermore, OLEDs can be driven by low-voltage DC, have a fast response time, and, most notably, are inexpensive to manufacture.

An organic light emitting display apparatus has a structure in which an organic light emitting element including a light emitting layer is provided between a cathode that injects electrons and an anode that injects holes. The organic light emitting display apparatus is a display

apparatus that utilizes the principle that when electrons generated from the cathode and holes generated from the anode are injected into the light emitting layer, the injected electrons and holes combine to generate excitons, and the generated excitons fall from an excited state to a ground state, thereby emitting light.

The conventional display apparatuses have multiple pixels, each containing four sub pixels: red, green, blue, and white. Because each pixel in such a conventional display apparatus contains four sub pixels, there can be a limit to how small a pixel can be.

### SUMMARY OF THE DISCLOSURE

The present disclosure is designed to solve or address the above-mentioned problem and other limitations associated with the related art.

The present disclosure aims to provide a display apparatus that can reduce the area of a pixel by arranging three sub pixels in one pixel, and can prevent or minimize a decrease in user visibility by displaying a color not included in one pixel using sub pixels provided in another adjacent pixel.

In order to achieve the above objects and other features, the present disclosure provides a display apparatus comprising a first pixel including three sub pixels configured to display different colors, and a second pixel adjacent to the first pixel and including three sub pixels configured to display different colors, wherein one sub pixel among the three sub pixels of the second pixel is configured to display a color different from the colors displayed or displayable by the three sub pixels of the first pixel.

Furthermore, one or more aspects of the present disclosure provide a display apparatus comprising a first pixel including a red sub pixel, a green sub pixel, and a blue sub pixel, a second pixel adjacent to the first pixel and including a red sub pixel, a green sub pixel, and a white sub pixel, and a third pixel adjacent to the first pixel and including a blue sub pixel, a green sub pixel, and a white sub pixel, wherein the white sub pixel of the second pixel and the white sub pixel of the third pixel are disposed adjacent to the first pixel.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic perspective view of a display apparatus according to one or more embodiments of the present disclosure.

FIG. 2 is a plan view schematically showing a display apparatus according to one or more embodiments of the present disclosure.

FIG. 3 is a plan view of a display apparatus according to one embodiment of the present disclosure. In this case, FIG. 3 is an enlarged view of area A of FIG. 2.

FIG. 4 is a plan view of a display apparatus according to one embodiment of the present disclosure. In this case, FIG. 4 is an enlarged view of one pixel among the plurality of pixels of FIG. 3.

FIG. 5 is a cross-sectional view of a display apparatus according to one embodiment of the present disclosure. In this case, FIG. 5 corresponds to cross-section I-I' of FIG. 4.

FIGS. 6A to 6C are drawings for explaining the driving mode in the surface image and line image of the display apparatus according to one embodiment of the present disclosure.

FIG. 7 is a plan view of a display apparatus according to another embodiment of the present disclosure. In this case, FIG. 7 is an enlarged view of area A of FIG. 2.

FIG. 8 is a plan view of a display apparatus according to another embodiment of the present disclosure. In this case, FIG. 8 is an enlarged view of area A of FIG. 2.

FIG. 9A and FIG. 9B are drawings for explaining the driving mode in the surface image and line image of the display apparatus according to another embodiment of the present disclosure.

FIG. 10 is a plan view of a display apparatus according to another embodiment of the present disclosure, which is an enlarged view of area A of FIG. 2.

FIG. 11A and FIG. 11B are drawings for explaining the driving mode in the surface image and line image of the display apparatus according to another embodiment of the present disclosure.

FIG. 12 is a plan view of a display apparatus according to another embodiment of the present disclosure, which is an enlarged view of area A of FIG. 2.

### DETAILED DESCRIPTION OF THE EMBODIMENTS

The advantages and features of the present disclosure, and the methods for achieving them, will become clearer with reference to the embodiments described in detail below together with the accompanying drawings. However, the present disclosure is not limited to the embodiments disclosed below, but can be implemented in various different forms. These embodiments are provided solely to ensure that the disclosure of the present disclosure is complete and to fully inform those skilled in the art of the scope of the invention, and the present disclosure is defined solely by the scope of the claims.

The shapes, sizes, ratios, angles, numbers, etc. disclosed in the drawings for explaining embodiments of the present disclosure are illustrative and are not limited to the matters illustrated in the drawings. Like reference numerals refer to like components throughout the specification. In addition, in describing the present disclosure, if a detailed description of a related known technology is judged to unnecessarily obscure the gist of the present disclosure, the detailed description thereof will be omitted. When the terms such as “includes,” “has,” and “consists of” are used in this specification, other parts can be added unless “only” is used. When a component is expressed in the singular, it includes a case where the plural is included unless there is a specifically explicit description.

When interpreting a component, it is interpreted as including the error range even if there is no separate explicit description.

When describing a positional relationship, for example, when the positional relationship between two parts is described using terms such as 'on top of', 'upper part of', 'lower part of', 'next to', etc., one or more other parts can be located between the two parts, unless 'right away' or 'directly' is used.

When describing a temporal relationship, for example, when the temporal continuity is described using terms such as 'after', 'following', 'next to', 'before', etc., it can also include cases where it is not continuous, as long as 'right away' or 'directly' is not used.

While terms like "first" and "second" are used to describe various components, these components are not limited by these terms. These terms are merely used to distinguish one component from another and may not define order or sequence. Therefore, a "first" component referred to below can also be a "second" component within the technical scope of the present disclosure. Further, the term “can” fully encompasses all the meanings and coverages of the term “may” and vice versa.

The features of each of the various embodiments of the present disclosure can be partially or wholly combined or combined with each other, and various technical connections and operations are possible, and each embodiment can be implemented independently of each other or implemented together in a related relationship.

Hereinafter, various embodiments of the present disclosure will be described in detail with reference to the drawings. All the components of each display apparatus/device according to all embodiments of the present disclosure are operatively coupled and configured.

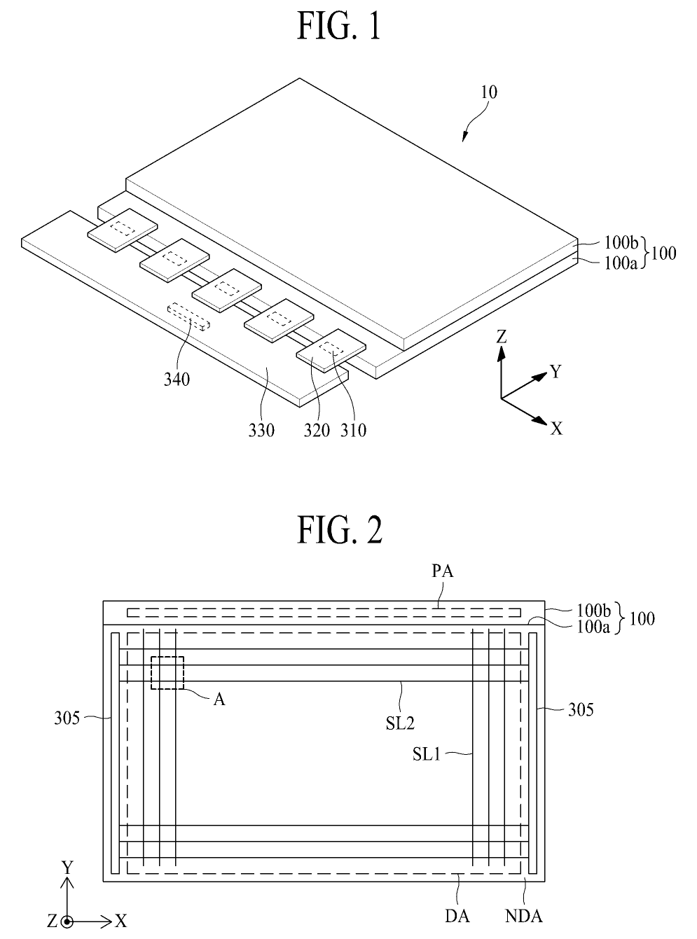

FIG. 1 is a perspective view schematically showing a display apparatus according to one or more embodiments of the present disclosure, and FIG. 2 is a plan view schematically showing a display apparatus according to one or more embodiments of the present disclosure.

Hereinafter, the X-axis represents the vertical direction, or the direction parallel to the gate line or the second signal line, the Y-axis represents the horizontal direction, or the direction parallel to the data line or the first signal line, and the Z-axis represents the height direction of the display apparatus 10.

The display apparatus 10 according to one embodiment of the present disclosure has been described with a focus on being implemented as an organic light emitting display, but can also be implemented as a liquid crystal display, a plasma display panel (PDP), a quantum dot light emitting display (QLED), or an electrophoresis display.

Referring to FIGS. 1 and 2, a display apparatus 10 according to one embodiment of the present disclosure includes a display panel 100, a source drive integrated circuit (hereinafter referred to as “IC”) 310, a flexible film 320, a circuit board 330, and a timing control unit 340.

The display panel 100 includes the first substrate 100a and the second substrate 100b facing each other. The second substrate 100b can be an encapsulation substrate. The first substrate 100a can be a plastic film, a glass substrate, or a silicon wafer substrate formed using a semiconductor process. The second substrate 100b can be a plastic film, a glass substrate, or an encapsulation film. The first substrate 100a and the second substrate 100b can be made of a transparent material.

The display panel 100 can be divided into a display area DA where pixels are formed to display an image and a non-display area NDA where no image is displayed.

The display area DA can be provided with first signal lines SL1, second signal lines SL2 and pixels, and the non-display area NDA can be provided with a pad area PA in which pads are arranged and at least one scan driver 305.

The first signal lines SL1 can extend in a first direction (e.g., Y-axis direction) and can intersect with the second signal lines SL2 in the display area DA. The second signal lines SL2 can extend in a second direction (e.g., X-axis direction) in the display area DA. The pixels are provided in an area where the first signal line SL1 is provided or an area where the first signal line SL1 and the second signal line SL2 intersect, and emit a predetermined light to display an image.

The source drive IC 310 receives digital video data and a source control signal from the timing control unit 340. The source drive IC 310 converts digital video data into analog data voltages according to the source control signal and supplies the converted data voltages to data lines. When the source drive IC 310 is manufactured as a driving chip, it can be mounted on the flexible film 320 in a COF (chip on film) or COP (chip on plastic) method.

The flexible film 320 can be formed with wires connecting the pads and the source drive IC 310, and wires connecting the pads and the wires of the circuit board 330. The flexible film 320 is attached onto the pads using an anisotropic conducting film, thereby connecting the pads and the wires of the flexible film 320.

The circuit board 330 can be attached to the flexible films 320. The circuit board 330 can have a plurality of circuits implemented with driving chips mounted thereon. For example, the timing control unit 340 can be mounted on the circuit board 330. The circuit board 330 can be a printed circuit board or a flexible printed circuit board.

The timing control unit 340 receives digital video data and a timing signal from an external system board. The timing control unit 340 generates a gate control signal for controlling the operation timing of the scan driver based on the timing signal and a source control signal for controlling the source drive ICs 310. The timing control unit 340 supplies the gate control signal to the gate driver 305 and the source control signal to the source drive IC 310.

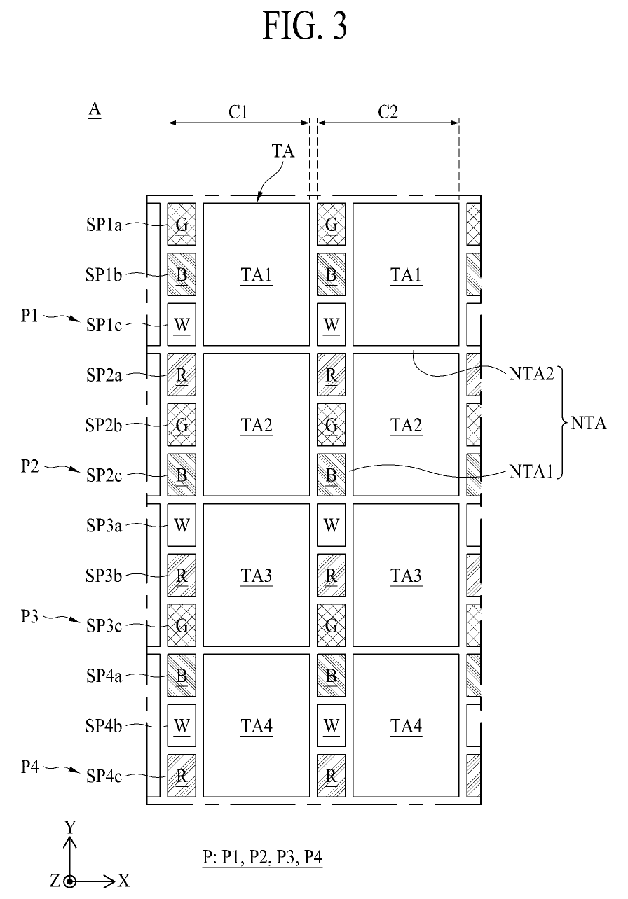

FIG. 3 is a plan view of a display apparatus according to one embodiment of the present disclosure. In this case, FIG. 3 is an enlarged view of area A of FIG. 2.

Referring to FIG. 3, a display apparatus according to one embodiment of the present disclosure comprises a plurality of pixels P, a non-transmissive area NTA, and a plurality of transmissive area TA.

The plurality of transmissive area TA are regions that allow most of the light incident from the outside to pass through, and the non-transmissive areas NTA and the plurality of pixels P are regions that do not allow most of the light incident from the outside to pass through. In this case, the light transmittance of the plurality of transmissive area TA can be higher than the light transmittance of the non-transmissive areas NTA and the plurality of pixels P. Since the display panel 100 includes the plurality of transmissive area TA, an object or background disposed on the back surface of the display panel (see 100 of FIG. 1) can be recognized.

The plurality of transmissive area TA can be arranged in a second direction Y, for example, a vertical direction, with a second non-transmissive area NTA2 interposed between them in each column C1, C2. In addition, the plurality of transmissive area TA can be arranged in a first direction X, for example, a horizontal direction, with a first non-transmissive area NTA1 and a pixel P interposed between them in each row.

The area of each of the plurality of transmissive areas TA can be formed to be larger than the area of any one of the sub pixels provided in each pixel P.

The plurality of transmissive areas TA can include, for example, a first transmissive area TA1, a second transmissive area TA2, a third transmissive area TA3, and a fourth transmissive area TA4 arranged in each column C1, C2. The first transmissive area TA1 to the fourth transmissive area TA4 can be repeatedly arranged along the second direction Y while being spaced apart from each other with the second non-transmissive area NTA2 interposed therebetween.

The plurality of pixels P can include, for example, a first pixel P1, a second pixel P2, a third pixel P3, and a fourth pixel P4 arranged in each column C1, C2. The first pixel P1 to the fourth pixel P4 can be repeatedly arranged along the second direction Y.

The plurality of pixels P can be disposed on one side of the plurality of transmissive areas TA in each column C1, C2. For example, the first pixel P1 can be disposed on one side of the first transmissive area TA1, for example, on the left side, the second pixel P2 can be disposed on one side of the second transmissive area TA2, for example, on the left side, the third pixel P3 can be disposed on one side of the third transmissive area TA3, for example, on the left side, and the fourth pixel P4 can be disposed on one side of the fourth transmissive area TA4, for example, on the left side.

Each of the first pixel P1 to the fourth pixel P4 can include three sub pixels that display different colors. The first pixel P1 can include a 1-1 sub pixel SP1a, a 1-2 sub pixel SP1b, and a 1-3 sub pixel SP1c, the second pixel P2 can include a 2-1 sub pixel SP2a, a 2-2sub pixel SP2b, and a 2-3 sub pixel SP2c, the third pixel P3 can include a 3-1 sub pixel SP3a, a 3-2 sub pixel SP3b, and a 3-3 sub pixel SP3c, and the fourth pixel P4 can include a 4-1 sub pixel SP4a, a 4-2 sub pixel SP4b, and a 4-3 sub pixel SP4c.

Any one of the plurality of pixels P can be configured by combining three sub pixels that emit light of any one color among red R, green G, blue B, and white W. In this case, each pixel P1, P2, P3, P3 can include three sub pixels having different combinations. For example, the first pixel P1 includes a 1-1 sub pixel SP1a that emits green light, a 1-2 sub pixel SP1b that emits blue light, and a 1-3 sub pixel SP1c that emits white light, the second pixel P2 includes a 2-1 sub pixel SP2a that emits red light, a 2-2 sub pixel SP2b that emits green light, and a 2-3 sub pixel SP2c that emits blue light, the third pixel P3 includes a 3-1 sub pixel SP3a that emits white light, a 3-2 sub pixel SP3b that emits red light, and a 3-3 sub pixel SP3c that emits green light, and the fourth pixel P4 includes a 4-1 sub pixel SP4a that emits blue light, and a 4-2 sub pixel SP1c that emits white light. It can be formed by including a pixel SP4b and a 4-3 sub pixel SP4c that emits red light.

In the same column C1, C2, sub pixels emitting red, green, blue, and white light can be sequentially and repeatedly arranged along the second direction Y. For example, in the same column C1, C2, sub pixels emitting red, green, blue, and white light can be sequentially and repeatedly arranged along the second direction Y, or can be sequentially and repeatedly arranged in the order of red, blue, white, and green, or can be sequentially and repeatedly arranged in the order of red, white, green, and blue. For example, in the same column C1, C2, the order among red, green, blue, and white can be variously changed.

According to one embodiment of the present disclosure, by arranging three sub pixels in combination in one pixel among the plurality of pixels P, the size of the pixel can be reduced compared to the conventional case where four sub pixels are arranged in combination in one pixel, and accordingly, the area of the transmissive areas TA1, TA2, TA3, TA4 can be increased, thereby improving the transparency of the display apparatus. Accordingly, an object disposed on the back of the display apparatus according to one embodiment of the present disclosure can be viewed more clearly.

Among the plurality of pixels P, one pixel comprises three sub pixels that display different colors among red, green, blue, and white, and at this time, among the three sub pixels provided in a pixel adjacent to one pixel, the sub pixel provided most adjacent to one pixel can display a color different from the three sub pixels provided in one pixel.

For example, the second pixel P2 includes the 2-1 sub pixel SP2a, the 2-2 sub pixel SP2b, and the 2-3 sub pixel SP2c, which display red, green, and blue, respectively. In this case, among the 1-1 sub pixels SP1a to the 1-3 sub pixels SP1c of the first pixel P1 adjacent to the second pixel P2, the 1-3 sub pixel SP1c that is most adjacent to the second pixel SP2 can display white. In addition, among the 3-1 sub pixels SP3a to the 3-3 sub pixels SP3c of the third pixel P3 adjacent to the second pixel P2, the 3-1 sub pixel SP3a that is most adjacent to the second pixel SP2 can display white.

Similarly, the third pixel P3 includes the 3-1 sub pixel SP3a, the 3-2 sub pixel SP3b, and the 3-3 sub pixel SP3c, which display white, red, and green, respectively. In this case, among the 2-1 sub pixel SP2a to the 2-3 sub pixel SP2c of the second pixel P2 adjacent to the third pixel P3, the 2-3 sub pixel SP2c that is most adjacent to the third pixel P3 can display blue. In addition, among the 4-1 sub pixel SP4a to the 4-3 sub pixel SP4c of the 4th pixel P4 adjacent to the 3 pixel P3, the 4-1 sub pixel SP4a that is most adjacent to the 3 pixel P3 can display blue.

According to one embodiment of the present disclosure, a color that cannot be displayed by three sub pixels provided in one pixel among the plurality of pixels P is displayed using sub pixels provided in other adjacent pixels among the plurality of pixels P, so that the user's visibility of adjacent pixels among the plurality of pixels P may not decrease. For example, the second pixel P2 includes red, green, and blue sub pixels, but since the 1-3 sub pixel SP1c and the 3-1 sub pixel SP3a that display white are provided in an area adjacent to the second pixel P2, the user can perceive that red, green, blue, and white are all displayed in the second pixel P2. Therefore, it is possible to expand the area of the transparent portion in the area adjacent to the second pixel P2 without decreasing the user's visibility.

The non-transmissive area NTA can include a first non-transmissive area NTA1 and a second non-transmissive area NTA2.

The first non-transmissive area NTA1 can extend in a second direction (e.g., in the Y-axis direction) in the display area (see DA in FIG. 2). In the display panel see 100 in FIG. 2, a plurality of the first non-transmissive areas NTA can be spaced apart from each other, and one of the plurality of transmissive area TA can be provided between two adjacent first non-transmissive areas NTA. In the first non-transmissive areas NTA1, first signal lines (see SL1 in FIG. 2) extending in the second direction (e.g., in the Y-axis direction) can be spaced apart from each other.

The first signal lines (see SL1 in FIG. 2) can include, for example, at least one of a common power line, a reference line, data lines, and a pixel power line.

The pixel power line can supply first power to the driving thin film transistor of each of the sub pixels provided in the plurality of pixels P. The pixel power line can also be referred to as a high-potential voltage line.

The common power line can supply a second power to the cathode electrodes of the sub pixels provided in the plurality of pixels P. At this time, the second power can be a common power that is commonly supplied to the sub pixels. The common power line can also be referred to as a low-potential voltage line.

The reference line can supply an initialization voltage (or reference voltage) to the driving thin film transistor of each of the sub pixels provided in the plurality of pixels P.

Each of the above data lines can supply a data voltage or a data signal to the sub pixels.

The second non-transmissive area NTA2 can extend in a first direction (e.g., X-axis direction) in the display area (see DA of FIG. 2). In the display panel (see 100 of FIG. 2), a plurality of second non-transmissive areas NTA can be spaced apart from each other, and one of the plurality of transmissive area TA can be provided between two adjacent second non-transmissive areas NTA. A second signal line SL2 can be arranged in the second non-transmissive area NTA2.

The second signal line SL2 extends in a first direction (e.g., X-axis direction) and can include, for example, a gate line. The gate line can supply a gate signal to the sub pixels provided in the plurality of pixels P.

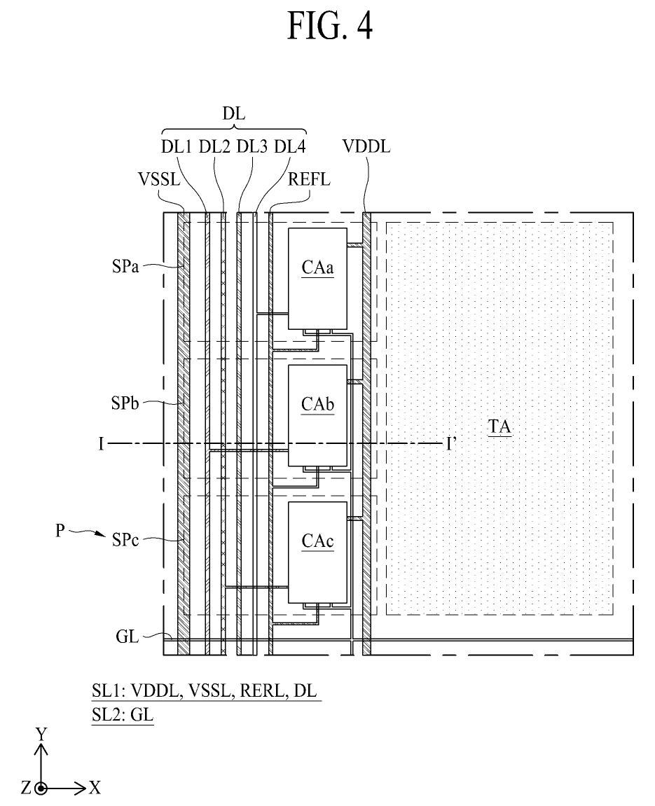

FIG. 4 is a plan view of a display apparatus according to one embodiment of the present disclosure. In this case, FIG. 4 is an enlarged view of one pixel and one transmissive area among the plurality of pixels and the plurality of transmissive areas of FIG. 3.

Referring to FIG. 4, a display apparatus according to one embodiment of the present disclosure can include a transmissive area TA, a pixel P, a first signal line SL1, and a second signal line SL2.

The pixel P can be disposed on one side of the transmissive area TA, for example, on the left side. The pixel P can include, for example, a first sub pixel SPa displaying white W, a second sub pixel SPb displaying red R, and a third sub pixel SPc displaying green G. The first to third sub pixels SPa to SPc can be spaced apart from each other along the second direction Y.

Each of the first sub pixel SPa to the third sub pixel SPc includes a circuit unit CAa, CAb, CAc for driving the first sub pixel SPa to the third sub pixel SPc. The circuit unit CAa, CAb, CAc includes, for example, a driving thin film transistor for driving the sub pixels, a switching transistor connected to the driving thin film transistor, and a capacitor for maintaining a data voltage for one frame.

The first signal line SL1 can be provided to overlap the first sub pixel SPa to the third sub pixel SPc.

The first signal line SL1 includes a common power line VSSL, a data line DL, a reference line REFL, and a pixel power line VDDL.

The data line DL includes a first data line DL1 for transmitting a data signal for red R, a second data line DL2 for transmitting a data signal for green G, a third data line DL3 for transmitting a data signal for blue B, and a fourth data line DL4 for transmitting a data signal for white W. The first data line DL1 to the fourth data line DL4 can extend along the second direction Y and be spaced apart from each other in the first direction X.

Each of the first data line DL1 to the fourth data line DL4 can overlap the first sub pixel SPa, the second sub pixel SPb, and the third sub pixel SPc.

The first data line DL1 is connected to the second circuit unit CAb provided in the second sub pixel SPb and can transmit a data signal for red to the second circuit unit CAb, the second data line DL2 is connected to the third circuit unit CAc provided in the third sub pixel SPc and can transmit a data signal for green to the third circuit unit CAc, and the fourth data line DL4 is connected to the first circuit unit CAa provided in the first sub pixel SPa and can transmit a data signal for white to the first circuit unit CAa. Meanwhile, among the sub pixels SPa, SPb, SPc provided in the pixel P illustrated in FIG. 4, the sub pixel connected to the third data line DL3 is not provided. The third data line DL3 is connected to a sub pixel provided in another pixel adjacent to the pixel P and can transmit a data signal for blue.

The second signal line SL2 can include a gate line GL. The gate line GL can be disposed on one side, for example, the lower side, of the pixel P and the transmissive area TA so as not to overlap with the pixel P and the transmissive area TA, but is not limited thereto. The gate line GL can be connected to circuit units CAa, CAb, CAc provided in each of the first to third sub pixels SPa to transmit a gate signal to the circuit units CAa, CAb, CAc.

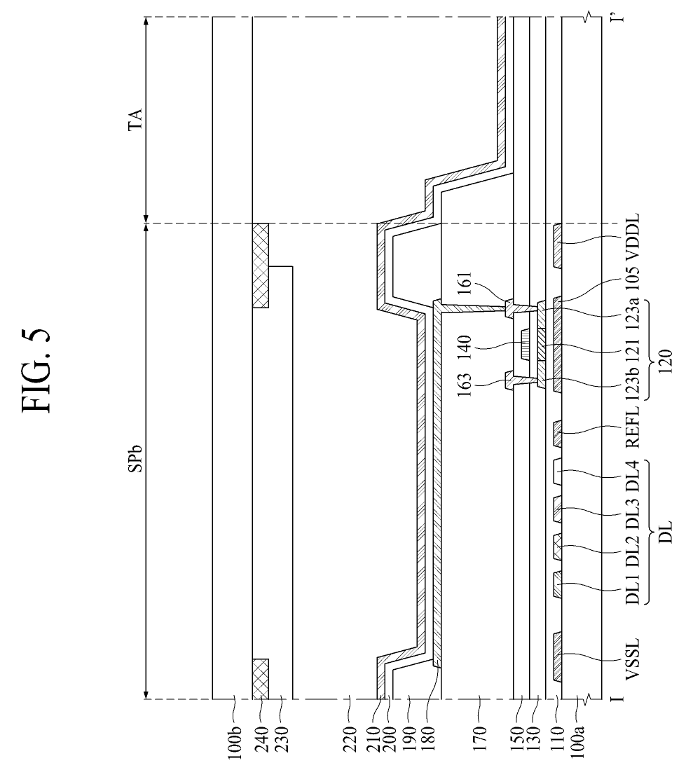

FIG. 5 is a cross-sectional view of a display apparatus according to one embodiment of the present disclosure. In this case, FIG. 5 corresponds to cross-section I-I’ of FIG. 4.

Referring to FIG. 5, a display apparatus according to an embodiment of the present disclosure includes a first substrate 100a, a light shielding layer 105, a high-potential power line VDDL, a reference line REFL, a data line DL, a low-potential power line VSSL, a buffer layer 110, an active layer 120, a gate insulating layer 130, a gate electrode 140, an interlayer insulating layer 150, a source electrode 161, a drain electrode 163, a planarization layer 170, a first electrode 180, a bank 190, a light emitting layer 200, a second electrode 210, an encapsulating layer 220, a color filter 230, a black matrix 240, and a second substrate 100b.

The first substrate 100a can be made of glass or plastic. In particular, the first substrate 100a can be made of a transparent plastic having flexible properties, for example, polyimide. When polyimide is used as the first substrate 100a, considering that a high-temperature deposition process is performed on the first substrate 100a, a heat-resistant polyimide that can withstand high temperatures can be used.

The high-potential voltage line VDDL, the light shielding layer 105, the reference line REFL, the data line DL, and the low-potential voltage line VSSL can be formed on the first substrate 100a. The high-potential voltage line VDDL, the light shielding layer 105, the reference line REFL, the data line DL, and the low-potential voltage line VSSL can be formed using the same material in the same process, but are not limited thereto.

The data line DL can include a first data line DL1, a second data line DL2, a third data line DL3, and a fourth data line DL4. Meanwhile, in FIG. 5, only the first data line DL1 to the fourth data line DL4 are illustrated as being formed on the same layer on the first substrate 100a, but this is not limited thereto, and the first data line DL1 to the fourth data line DL4 can be formed on different layers.

The light shielding layer 105 can be formed to overlap with the active layer 120. In detail, the light shielding layer 105 is provided to overlap with the channel part 121 of the active layer 120, thereby preventing light entering from the lower surface of the first substrate 100a from entering the inside of the channel part 121 of the active layer 120. Accordingly, it is possible to prevent defects from occurring in the active layer 120 due to light entering from the lower surface of the first substrate 100a.

The buffer layer 110 can be disposed on the first substrate 100a to cover the high-potential voltage line VDDL, the light shielding layer 105, the reference line REFL, the data line DL, and the low-potential voltage line VSSL.

The active layer 120 can be formed on the above buffer layer 110. The active layer 120 can be formed of a semiconductor material, for example, any one of amorphous silicon (a-Si), polycrystalline silicon (Poly Si), and oxide semiconductor materials.

The active layer 120 is formed by overlapping the gate electrode 140 and including a channel part 121 made of a non-conductive semiconductor material, a first connection part 123a provided on one side of the channel part 121, for example, on the left side, and obtained by a conductorized process for the semiconductor material, and a second connection part 123b provided on the other side of the channel part 121, for example, on the right side, and obtained by a conductive process for the semiconductor material.

The first connection part 123a and the second connection part 123b formed by the conductorized process can serve as electrodes or wiring. For example, the second connection part 123b can serve as a drain electrode 163.

The gate insulating layer 130 can be formed on the active layer 120 and the second buffer layer 110b. In some cases, the gate insulating layer 130 can be formed in the same pattern as the gate electrode 140 and the gate insulating layer 130.

The gate electrode 140 can be formed on the gate insulating layer 130.

The interlayer insulating layer 150 can be formed on the gate electrode 140. The interlayer insulating layer 150 insulates between the gate electrode 140 and the source electrode 161 and between the gate electrode 140 and the drain electrode 163.

The contact hole can be formed in the interlayer insulating layer 150. Accordingly, a portion of the upper surface of the first connection part 123a of the active layer 120 can be exposed by one contact hole, and further, a portion of the upper surface of the second connection part 123b of the active layer 120 can be exposed by another contact hole.

The source electrode 161 and the drain electrode 163 can be disposed on the interlayer insulating layer 150.

The source electrode 161 can be electrically connected to the first connection part 123a of the active side 120 by a contact hole, and the drain electrode 163 can be electrically connected to the second connection part 123b of the active layer 120 by a contact hole.

The planarization layer 170 can be formed on the interlayer insulating layer 150, the source electrode 161, and the drain electrode 163. The planarization layer 170 can be formed on the source electrode 161 and the drain electrode 163 so that the upper surface of the planarization layer 170 can be planarized.

The planarization layer 170 is provided with a contact hole, and a portion of the upper surface of the source electrode 161 can be exposed through the contact hole. However, in some cases, a portion of the upper surface of the drain electrode 163 can be exposed through the contact hole.

The planarization layer 170 can be formed on the sub pixels (see SPa to SPc in FIG. 4) and may not be formed on the transmissive area TA. However, the present disclosure is not limited thereto, and the planarization layer 170 can be formed across the sub pixels (see SPa to SPc in FIG. 4) and the transmissive area TA.

The first electrode 180 can be formed on the planarization layer 170 and can be electrically connected to the source electrode 161 through a contact hole provided in the planarization layer 170. Meanwhile, in some cases, the first electrode 180 can be electrically connected to the drain electrode 163 through a contact hole provided in the planarization layer 170. The first electrode 180 can function as an anode.

The first electrode 180 can be provided to overlap all of the first data line DL1 to the fourth data line DL4. However, it is not limited thereto.

The bank 190 can be formed on the first electrode 180. In this case, a portion of the upper surface of the first electrode 180 that is exposed and not covered by the bank 190 becomes a light emitting area.

The light emitting layer 200 can be formed on the first electrode 180. The light emitting layer 200 can include red, green, and blue light emitting layers patterned for each sub pixel, or can be formed of a white light emitting layer connected to all pixels. When the light emitting layer 200 is formed of a white light emitting layer, the light emitting layer 200 can include, for example, a first stack including a blue light emitting layer, for example, a second stack including a yellow-green light emitting layer, and a charge generation layer provided between the first stack and the second stack, but is not necessarily limited thereto.

The light emitting layer 200 can be formed over the entire surface of the second sub pixel SPb and the transmissive area TA, but is not limited thereto.

The second electrode 210 can be formed on the light emitting layer 200. The second electrode 210 can function as a cathode.

The second electrode 210 can be formed, for example, on the bank 190 and the light emitting layer 200. Accordingly, the second electrode 210 can be formed over the entire surface of the second sub pixel SPb and the transmissive area TA. However, the present disclosure is not limited thereto.

The encapsulation layer 220 can be formed on the second electrode 210. The encapsulation layer 220 can be formed on the entire surface of the first substrate 100a. Accordingly, it can be formed on the entire surface of the second sub pixel SPb and the transmissive area TA.

Meanwhile, the sealing layer 220 can include a first sealing layer including an inorganic material, a second sealing layer including an organic material, and a third sealing layer including an inorganic material.

The color filter 230 can be formed on the sealing layer 220.

The color filter 230 can transmit light of any one of red, green, and blue colors. Accordingly, light emitted from the light emitting layer 200 provided in the second sub pixel SPb passes through the color filter 230 and is emitted to the outside. Meanwhile, if the second sub pixel SPb is a sub pixel that displays white light, the color filter 230 can be omitted.

The black matrix 250 can be formed on the sealing layer 220 and the color filter 230.

The black matrix 250 overlaps with the bank 190 and is formed between adjacent sub pixels (see SPa to SPc in FIG. 4), thereby preventing the problem of light emitted from each of the adjacent sub pixels (see SPa to SPc in FIG. 4) being mixed with each other and causing color mixing.

The second substrate 100b can be formed on the black matrix 250. The second substrate 100b can be joined to the first substrate 100a while facing it.

The second substrate 100b can be made of glass or plastic.

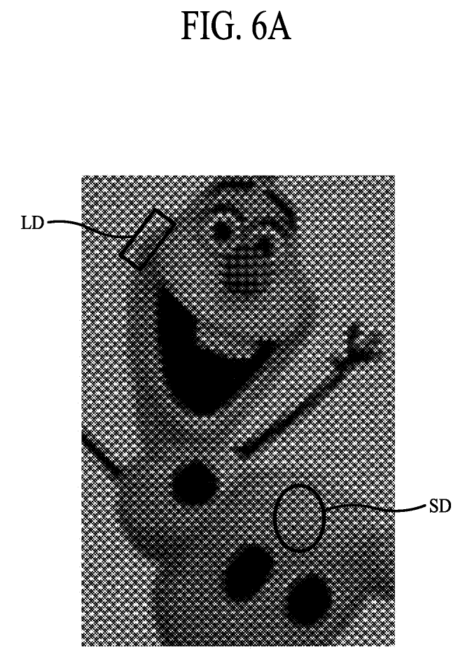

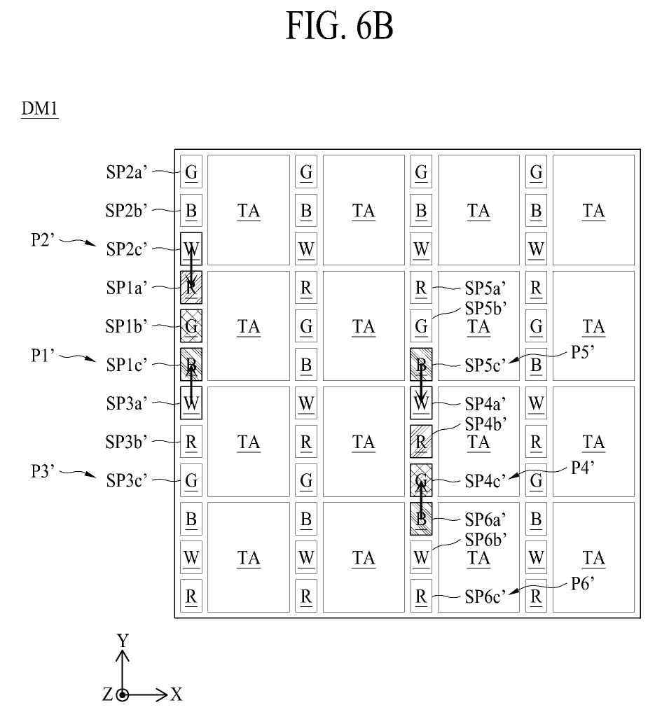

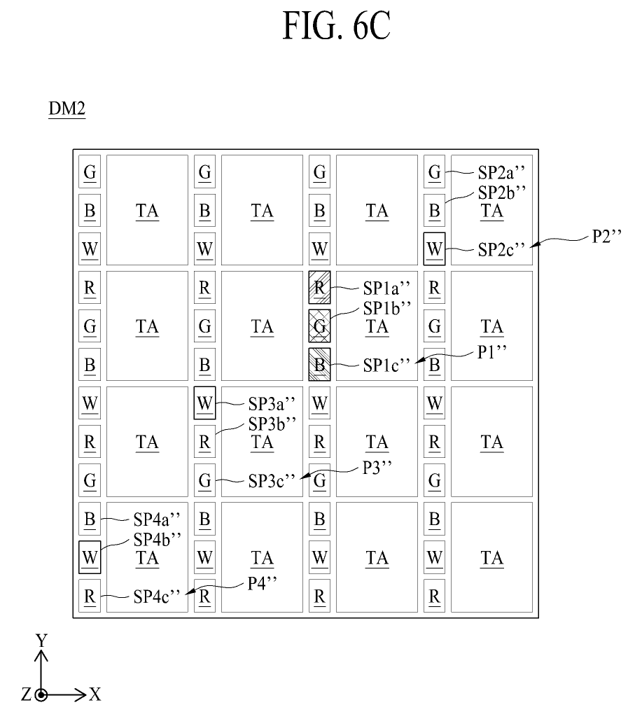

FIGS. 6A to 6C are drawings for explaining the driving mode in the surface image and line image of the display apparatus according to one embodiment of the present disclosure.

As can be seen from FIGS. 6A to 6C, the image displayed on the display panel (see 100 of FIG. 1) can include a line image LD and a surface image SD. According to an embodiment of the present disclosure, when the display apparatus displays the line image LD and the surface image SD, the power consumption can be reduced and the user's visibility can be improved by differentiating the driving forms of the plurality of pixels (see P of FIG. 3). In detail, by driving the plurality of pixels (see P of FIG. 3) by rendering, the driving modes can be made different for some pixels displaying the surface image SD among the plurality of pixels (see P of FIG. 3) and other pixels displaying the line image LD among the plurality of pixels (see P of FIG. 3), thereby reducing the power consumption of the entire pixels and improving the user's visibility.

In this case, the line image LD refers to an image or image representing a line formed between surfaces, and the above surface image SD refers to an image or image appearing in the remaining area excluding the line image LD, and can refer to the shape or background of an image appearing on a display panel (see 100 in FIG. 1).

According to a display apparatus according to an embodiment of the present disclosure, some pixels displaying the surface image SD among the plurality of pixels (see P of FIG. 3) can be driven in a first driving mode DM1, and other pixels displaying the line image LD among the plurality of pixels (see P of FIG. 3) can be driven in a second driving mode DM2.

First, referring to FIG. 6B, the display apparatus according to one embodiment of the present disclosure can drive some of the plurality of pixels P according to the first driving mode DM1 to display the surface image SD.

The first driving mode DM1 relates to a driving mode in which a color not displayed by the sub pixels of the first pixel P1' provided in the plurality of pixels P can be displayed using the sub pixels provided in the second pixel P2' and/or the third pixel P3' provided adjacent to the first pixel P1'.

In detail, when the first pixel P1' includes, for example, a 1-1 sub pixel SP1a' that displays red, a 1-2 sub pixel SP1b' that displays green, and a 1-3 sub pixel SP1c' that displays blue, the first pixel P1' does not have a sub pixel that displays white. In this case, in order to display white in an area adjacent to the first pixel P1', the 2-3 sub pixel SP2c' that is provided in the second pixel P2' and is most adjacent to the first pixel P1' can display white, and the 3-1 sub pixel SP3a' that is provided in the third pixel P3' and is most adjacent to the first pixel P1' can display white.

Accordingly, when the plurality of pixels P are driven according to the first driving mode DM1 to display the surface image SD, the sub pixels displaying white in an area adjacent to the first pixel P1', for example, the 2-3 sub pixel SP2c' and/or the 3-1 sub pixel SP3a', display white, so that the user can perceive that white light is displayed in the first pixel P1'.

In addition, when the fourth pixel P4' includes, for example, a 4-1 sub pixel SP4a' that displays white, a 4-2 sub pixel SP4b' that displays red, and a 4-3 sub pixel SP4c' that displays green, the fourth pixel P4' does not have a sub pixel that displays blue. In this case, in order to display blue in an area adjacent to the fourth pixel P4', the 5-3 sub pixel SP5c' that is provided in the fifth pixel P5' and is most adjacent to the fourth pixel P4' can display blue, and the 6-1 sub pixel SP6a' that is provided in the sixth pixel P6' and is most adjacent to the fourth pixel P4' can display blue.

Accordingly, when the plurality of pixels P are driven according to the first driving mode DM1 to display the surface image SD, the sub pixels displaying blue in an area adjacent to the fourth pixel P4', for example, the 5-3 sub pixel SP5c' and/or the 6-1 sub pixel SP6a', display blue, so that the user can perceive that blue light is displayed in the fourth pixel P4'.

Next, as can be seen in FIG. 6C, the display apparatus according to one embodiment of the present disclosure can drive other pixels among the plurality of pixels P according to the second driving mode DM2 to display the line image LD.

In the second driving mode DM2, white can be expressed by driving all sub pixels provided in some pixels that do not include white sub pixels among the plurality of pixels P to display the line image LD.

In detail, when the first pixel P1'' includes, for example, a 1-1 sub pixel SP1a'' for displaying red, a 1-2 sub pixel SP1b'' for displaying green, and a 1-3 sub pixel SP1c'' for displaying blue, all of the 1-1 sub pixels SP1a'' to the 1-3 sub pixels SP1c'' provided in the first pixel P1'' can be driven in the second driving mode DM2. In this case, white can be displayed while all of the red, green, and blue sub pixels are driven. At this time, in the second pixel P2'', only the white of the 2-3 sub pixel SP2c'' can be driven, but it is not necessarily limited thereto, and the blue of the 2-2 sub pixel SP2b'' can also be driven at a low gray level. In addition, in the third pixel P3'', only the white of the 3-1 sub pixel SP3a'' can be driven, but it is not necessarily limited to that, and the red of the 3-2 sub pixel SP3b'' can also be driven at a low gray level.

The line image LD can be perceived relatively more sensitively by the human eye than the surface image SD. Therefore, when displaying the line image LD, by driving the plurality of pixels P in the second driving mode DM2, white can be directly displayed in the pixels displaying the line image LD. In this way, by driving the plurality of pixels P in the second driving mode DM2, the smooth line image LD can be recognized by the user's eyes.

Meanwhile, in FIG. 6C, the line image LD is described as an example of a case in which the line image extends in a diagonal direction from the lower left to the upper right, but the line image LD according to the embodiment of the present disclosure is not limited thereto. The line image LD extending in the first direction X or the second direction Y can also be implemented with the plurality of pixels P driven by the second driving mode DM2.

According to one embodiment of the present disclosure, by applying the first driving mode DM1 and the second driving mode DM2 in combination according to the line image LD and the surface image SD, when the line image LD is displayed, the user's visibility can be improved, and when the surface image SD is displayed, the power consumption of each of the plurality of pixels P can be reduced.

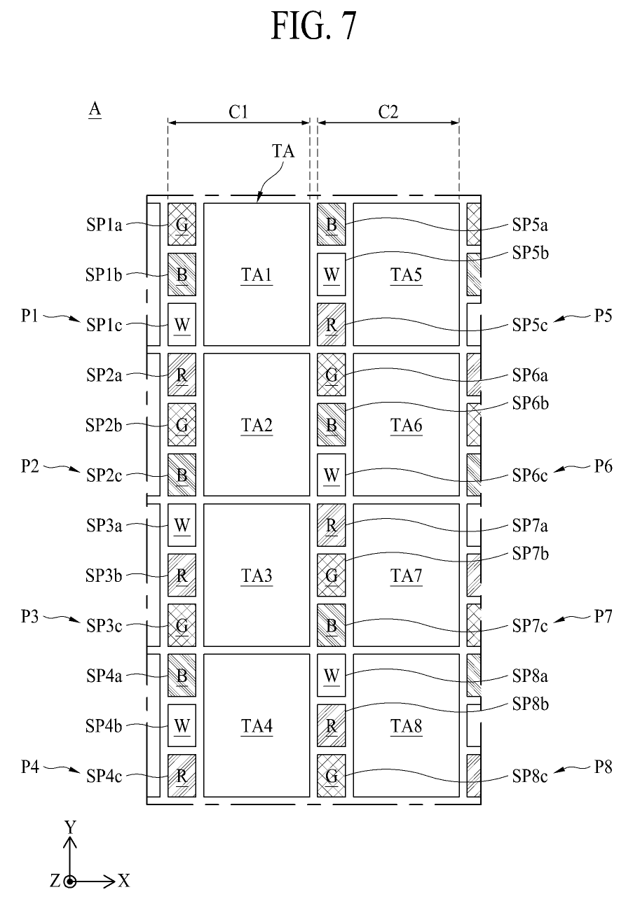

FIG. 7 is a plan view of a display apparatus according to another embodiment of the present disclosure. In this case, FIG. 7 is an enlarged view of area A of FIG. 2. Meanwhile, the embodiment of FIG. 7 is identical to the embodiment of FIG. 3 except for the arrangement of sub pixels provided in adjacent rows, and therefore, the following description will focus on the different configuration.

As can be seen from FIG. 7, a display apparatus according to another embodiment of the present disclosure can include a first column C1 extending in the first direction and a second column C2 extending in the first direction Y and adjacent to the first column C1. In this case, the order of the sub pixels in the first column C1 and the second column C2 can be arranged in the same arrangement. For example, among the plurality of pixels P, the 1-1 sub pixel SP1a of the first pixel P1 provided in the first column C1 to the 4-3 sub pixel SP4c of the fourth pixel P4 are arranged in order as sub pixels that display green, blue, white, and red light in that order, and the 5-1 sub pixel SP5a of the fifth pixel P5 provided in the second column C2 to the 8-3 sub pixel SP8c of the eighth pixel P8 are arranged in order as sub pixels that display blue, white, red, and green light in that order.

The first pixel P1 and the fifth pixel P5 can face each other based on the first transmissive area TA1, the second pixel P2 and the sixth pixel P6 can face each other based on the second transmissive area TA2, the third pixel P3 and the seventh pixel P7 can face each other based on the third transmissive area T3, and the fourth pixel P4 and the eighth pixel P8 can face each other based on the fourth transmissive area TA4.

Meanwhile, the display apparatus according to the embodiment of FIG. 3 has identical pixels having identical sub pixel arrangements arranged in the same row in the first direction X, whereas the display apparatus according to the embodiment of FIG. 7 can have different pixels having different sub pixel arrangements arranged in the same row in the first direction X.

In other words, in the display apparatus according to the embodiment of FIG. 3, the same pixels or sub pixels are arranged facing each other based on one of the plurality of transmissive areas TA in the first column C1 and the second column C2, whereas in the display apparatus according to the embodiment of FIG. 7, different pixels or sub pixels can be arranged facing each other based on one of the plurality of transmissive areas TA.

According to another embodiment of the present disclosure, one pixel provided on one side, for example, on the left side, based on one of the plurality of transmissive areas TA and another pixel provided on the other side, for example, on the right side, based on one of the plurality of transmissive areas TA can be formed by an arrangement of different sub pixels.

For example, the first pixel P1 including the 1-1 sub pixel SP1a to the 1-3 sub pixel SP1c faces the 5th pixel P5 including the 5-1 sub pixel SP5a to the 5-3 sub pixel SP5c through the first transmissive area TA1, but the 1-1 sub pixel SP1a to the 1-3 sub pixel SP1c are sequentially composed of green, blue, and white sub pixels, and the 5-1 sub pixel SP5a to the 5-3 sub pixel SP5c are sequentially composed of blue, white, and red sub pixels.

For example, the second pixel P2 including the 2-1 sub pixel SP2a to the 2-3 sub pixel SP2c faces the second transmissive area TA1 with the sixth pixel P6 including the 6-1 sub pixel SP6a to the 6-3 sub pixel SP6c, but the 2-1 sub pixel SP2a to the 2-3 sub pixel SP2c are sequentially composed of red, green, and blue sub pixels, and the 6-1 sub pixel SP6a to the 6-3 sub pixel SP6c are sequentially composed of green, blue, and white sub pixels.

For example, the third pixel P3 including the 3-1 sub pixel SP3a to the 3-3 sub pixel SP3c faces the third transmissive area TA1 with the 7th pixel P7 including the 7-1 sub pixel SP7a to the 7-3 sub pixel SP7c, but the 3-1 sub pixel SP3a to the 3-3 sub pixel SP3c are composed of white, red, and green sub pixels in that order, and the 7-1 sub pixel SP7a to the 7-3 sub pixel SP7c are composed of red, green, and blue sub pixels in that order.

For example, the fourth pixel P4 including the 4-1 sub pixel SP4a to the 4-3 sub pixel SP4c faces the fourth transmissive area TA1 with the eighth pixel P8 including the 8-1 sub pixel SP8a to the 8-3 sub pixel SP8c, but the 4-1 sub pixel SP4a to the 4-3 sub pixel SP4c are composed of blue, white, and red sub pixels in that order, and the 8-1 sub pixel SP8a to the 8-3 sub pixel SP8c are composed of white, red, and green sub pixels in that order.

According to another embodiment of the present disclosure, the arrangement of the sub pixels arranged in the first column C1 and the second column C2 among the plurality of pixels P is made the same, and the arrangement of any of the pixels P adjacent in the first direction X is arranged differently based on any one of the plurality of transmissive areas TA, thereby improving the user's visibility in the first direction X.

Meanwhile, the display apparatus according to the embodiment of FIG. 7 can also be driven in the first driving mode (see DM1 of FIG. 6B) and/or the second driving mode (see DM2 of FIG. 6C), as in the cases of FIGS. 6A to 6C described above.

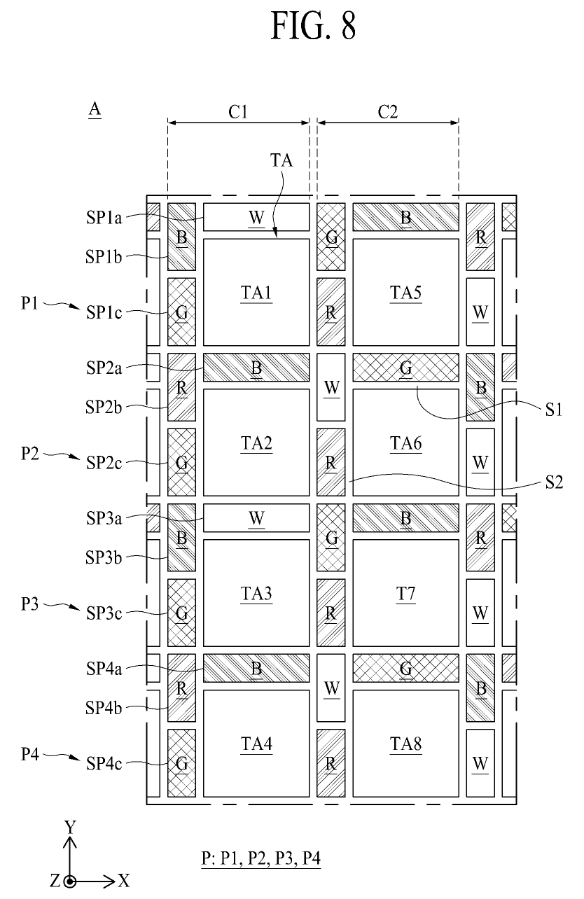

FIG. 8 is a plan view of a display apparatus according to another embodiment of the present disclosure. In this case, FIG. 8 is an enlarged view of area A of FIG. 2. Meanwhile, the embodiment of FIG. 8 is identical to the embodiment of FIG. 3 except for the arrangement of pixels, and therefore, the following description will focus on the different configurations.

Referring to FIG. 8, according to another embodiment of the present disclosure, any one of the plurality of pixels P can be formed along a first surface S1 of any one of the plurality of transmissive areas TA, for example, an upper surface, and a second surface S2 adjacent to the first surface S1, for example, a left surface. In detail, any one of three sub pixels provided in any one of the plurality of pixels P is provided on the first surface S1 of any one of the transmissive areas, and the remaining two sub pixels of the three sub pixels are provided on the second surface S2 of any one of the transmissive areas and are arranged along the second direction Y.

For example, the first pixel P1 can be disposed on one side of the first transmissive area TA1, the second pixel P2 can be disposed on one side of the second transmissive area TA2, the third pixel P3 can be disposed on one side of the third transmissive area TA3, and the fourth pixel P4 can be disposed on one side of the fourth transmissive area TA4.

The 1-1 sub pixel SP1a can be disposed on the first surface S1 of the first transmissive area TA1, and the 1-2 sub pixel SP1b and the 1-3 sub pixel SP1c can be arranged along the second direction Y on the second surface S2 of the first transmissive area TA1. For example, the 1-1 sub pixel SP1a can display white, the 1-2 sub pixel SP1b can display blue, and the 1-3 sub pixel SP1c can display green. The 2-1 sub pixel SP2a can be disposed on the first surface S1 of the second transmissive area TA2, and the 2-2 sub pixel SP2b and the 2-3 sub pixel SP2c can be arranged along the second direction Y on the second surface S2 of the second transmissive area TA2. For example, the 2-1 sub pixel SP2a can display blue, the 2-2 sub pixel SP2b can display red, and the 2-3 sub pixel SP2c can display green. The 3-1 sub pixel SP3a can be disposed on the first surface S1 of the third transmissive area TA3, and the 3-2 sub pixel SP3b and the 3-3 sub pixel SP3c can be arranged along the second direction Y on the second surface S2 of the third transmissive area TA3. For example, the 3-1 sub pixel SP3a can display white, the 3-2 sub pixel SP3b can display blue, and the 3-3 sub pixel SP3c can display green. The 4-1 sub pixel SP4a can be disposed on the first surface S1 of the fourth transmissive area TA4, and the 4-2 sub pixel SP4b and the 4-3 sub pixel SP4c can be arranged along the second direction Y on the second surface S2 of the fourth transmissive area TA4. For example, the 4-1 sub pixel SP4a can display blue, the 4-2 sub pixel SP4b can display red, and the 4-3 sub pixel SP4c can display green.

According to another embodiment of the present disclosure, sub pixels provided on the first surface S1 of the plurality of transmissive areas TA, for example, the 1-1 sub pixel SP1a, the 2-1 sub pixel SP2a, the 3-1 sub pixel SP3a, and the 4-1 sub pixel SP4a, are provided between the plurality of transmissive areas TA, so that sub pixels are provided between the first column C1 and the second column C2, thereby improving user visibility.

According to another embodiment of the present disclosure, one of the plurality of pixels P includes a sub pixel that displays a first color, which is one of red, green, blue, and white, a sub pixel that displays a second color, which is another color among red, green, blue, and white, and a sub pixel that displays a third color, which is another color among red, green, blue, and white. In this case, the pixel including the sub pixels that display light of the first color to the third color can display the fourth color by sub pixels that are provided in adjacent pixels and display a fourth color different from the first color to the third color among red, green, blue, and white.

For example, the second pixel P2 includes the 2-1 sub pixel SP2a for displaying blue, the 2-2 sub pixel SP2b for displaying red, and the 2-3 sub pixel SP2c for displaying green. In this case, white can be displayed in the second pixel P2 by a sub pixel for displaying white provided in any one of the plurality of pixels P provided adjacent to the second pixel P2 and the second transmissive area TA2. For example, white can be displayed by a white sub pixel provided on one side of the second transmissive area TA2, for example, on the right side, a white sub pixel provided on one side of the second pixel P2, for example, on the left side, and a white sub pixel provided on the other side of the second transmissive area TA2, for example, on the lower side. Therefore, even if a sub pixel for displaying white is not provided in the second pixel P2, the user's visibility may not be reduced.

The first non-transmissive area NTA1 described above is configured to include the first signal lines (see SL1 of FIG. 2). In this case, the first signal lines (see SL1 of FIG. 2) include, for example, at least one of a common power line, a reference line, data lines, and a pixel power line, so that two sub pixels arranged on the second surface S2 of one of the plurality of transmissive area TA can overlap with the first signal lines (see SL1 of FIG. 2). For example, the 1-2 sub pixel SP1b and the 1-3 sub pixel SP1c can overlap with the first signal lines (see SL1 of FIG. 2).

The second non-transmissive area NTA2 described above is formed by including the second signal lines (see SL2 of FIG. 2). In this case, the second signal lines (see SL2 of FIG. 2) can include, for example, gate lines, and thus, one sub pixel arranged on the first surface S1 of one of the plurality of transmissive area TA can overlap with the second signal line (see SL2 of FIG. 2). For example, the 1-1 sub pixel SP1a can overlap with the second signal line (see SL2 of FIG. 2).

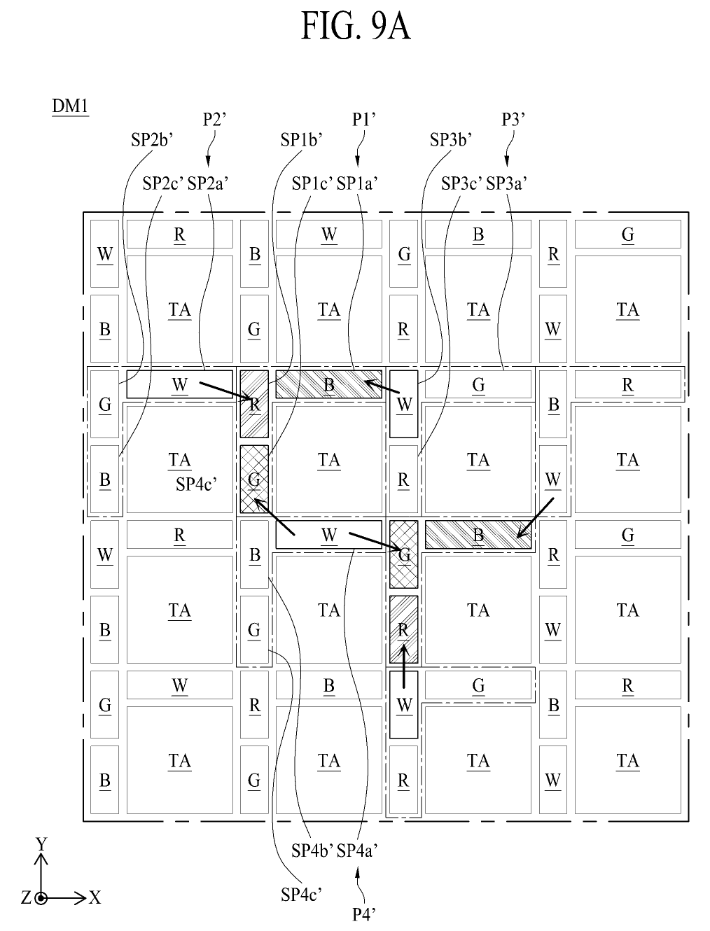

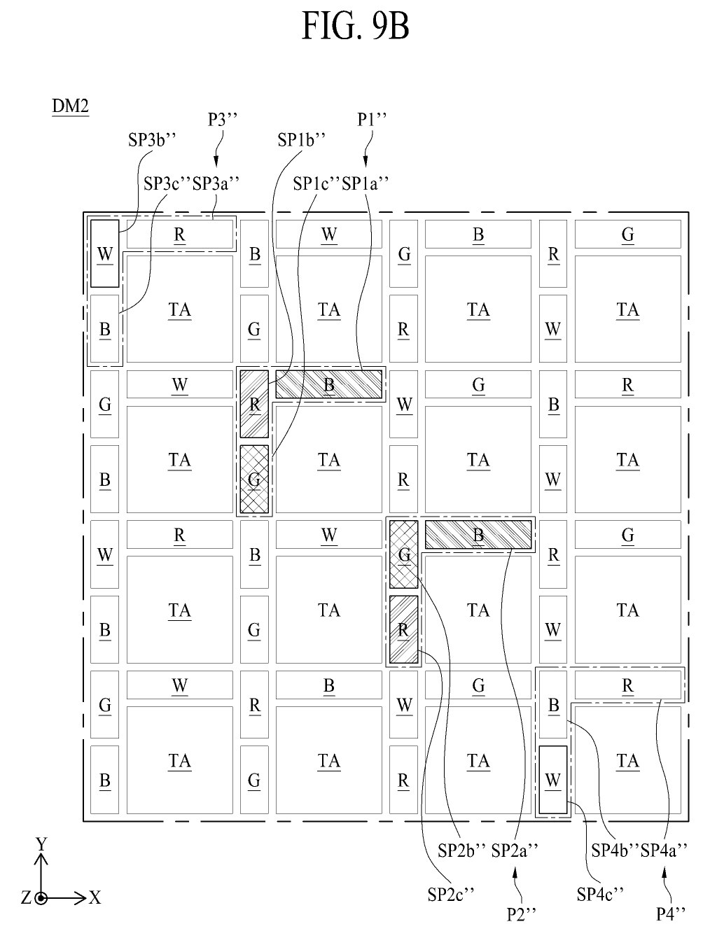

FIGS. 9A and 9B are diagrams for explaining the driving modes of a surface image and a line image of a display apparatus according to one embodiment of the present disclosure. In this case, FIGS. 9A and 9B briefly illustrate a plurality of transmissive areas and a plurality of pixels provided in the embodiment of FIG. 8. Therefore, a repeated explanation will be omitted.

According to another embodiment of the present disclosure, by rendering and driving the plurality of pixels (see P of FIG. 3), the driving modes of some pixels displaying the surface image SD among the plurality of pixels (see P of FIG. 3) and other pixels displaying the line image LD among the plurality of pixels (see P of FIG. 3) are made different, thereby reducing power consumption in all pixels and improving user visibility.

According to a display apparatus according to another embodiment of the present disclosure, some pixels among the plurality of pixels (see P of FIG. 8) that display the surface image (see SD of FIG. 6A) can be driven in a first driving mode DM1, and other pixels among the plurality of pixels (see P of FIG. 8) that display the line image (see LD of FIG. 6A) can be driven in a second driving mode DM2.

First, referring to FIG. 9A, a display apparatus according to another embodiment of the present disclosure can drive some of the plurality of pixels P according to the first driving mode DM1 to display the surface image (see SD of FIG. 6A).

The first driving mode DM1 relates to a driving mode in which a color not displayed by the sub pixels of the first pixel P1' provided in the plurality of pixels P can be displayed using the sub pixels provided in the second pixel P2', the third pixel P3', and/or the fourth pixel P4' provided adjacent to the first pixel P1'.

In detail, when the first pixel P1' includes, for example, a 1-1 sub pixel SP1a' that displays red, a 1-2 sub pixel SP1b' that displays green, and a 1-3 sub pixel SP1c' that displays blue, the first pixel P1' does not have a sub pixel that displays white. In this case, in order to display white in an area adjacent to the first pixel P1', the 2-1 sub pixel SP2a' provided in the second pixel P2' and most adjacent to the first pixel P1' can display white, the 3-2 sub pixel SP3b' provided in the third pixel P3' and most adjacent to the first pixel P1' can display white, and the 4-1 sub pixel SP4a' provided in the fourth pixel P4' and most adjacent to the first pixel P1' can display white.

Accordingly, when the plurality of pixels P are driven according to the first driving mode DM1 to display the surface image (see SD of FIG. 6A), the sub pixels displaying white in an area adjacent to the first pixel P1', for example, the 2-1 sub pixel SP2a', the 3-2 sub pixel SP3b', and/or the 4-1 sub pixel SP4a', display white, so that the user can recognize that white light is displayed in the first pixel P1'.

Next, referring to FIG. 9B, a display apparatus according to another embodiment of the present disclosure can drive other pixels among the plurality of pixels P according to the second driving mode DM2 to display the line image (see LD of FIG. 6A).

In the second driving mode DM2, white can be expressed by driving all sub pixels provided in some pixels that do not include white sub pixels among the plurality of pixels P to display the line image (see LD of FIG. 6A).

In detail, when the first pixel P1'' includes, for example, a 1-1 sub pixel SP1a'' for displaying red, a 1-2 sub pixel SP1b'' for displaying green, and a 1-3 sub pixel SP1c'' for displaying blue, all of the 1-1 sub pixels SP1a'' to the 1-3 sub pixels SP1c'' provided in the first pixel P1'' can be driven in the second driving mode DM2. In this case, white can be displayed while all of the red, green, and blue sub pixels are driven.

The line image (see LD of FIG. 6A) can be perceived relatively more sensitively by the human eye than the surface image (see SD of FIG. 6A). Therefore, when displaying the line image (see LD of FIG. 6A), by driving the plurality of pixels P with the second driving mode DM2, white can be directly displayed in the pixels displaying the line image (see LD of FIG. 6A). In this way, by driving the plurality of pixels P with the second driving mode DM2, the smooth line image (see LD of FIG. 6A) can be recognized by the user's eyes.

Meanwhile, in FIG. 9B, the line image (see LD of FIG. 6A) is described as an example of a case in which the line image extends in a diagonal direction from the upper left to the lower right, but the line image (see LD of FIG. 6A) in another embodiment of the present disclosure is not limited thereto. The line image (see LD of FIG. 6A) extending in the first direction X or the second direction Y can also be implemented with the plurality of pixels P driven by the second driving mode DM2.

According to one embodiment of the present disclosure, by applying and using the first driving mode DM1 and the second driving mode DM2 in combination according to the line image (see LD of FIG. 6A) and the surface image (see SD of FIG. 6A), when displaying the line image (see LD of FIG. 6A), the user's visibility can be improved, and when displaying the surface image (see SD of FIG. 6A), the power consumption of each of the plurality of pixels P can be reduced.

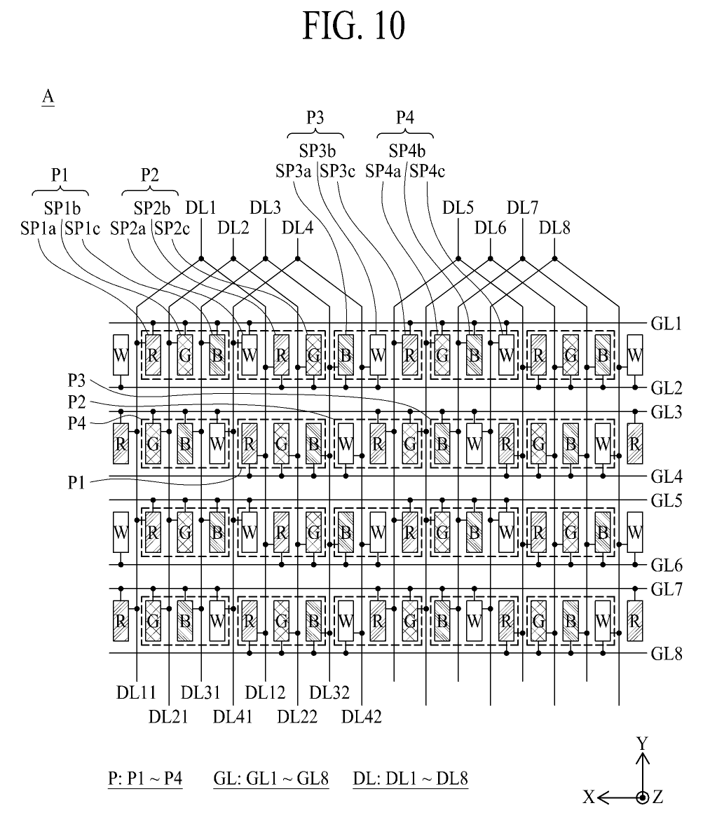

FIG. 10 is a plan view of a display apparatus according to another embodiment of the present disclosure, which is an enlarged view of area A of FIG. 2. FIG. 10 differs from the display apparatus according to the aforementioned embodiment in that it does not include a transmissive area.

Referring to FIG. 10, a display apparatus according to another embodiment of the present disclosure comprises a plurality of gate lines GL, a plurality of data lines DL, and a plurality of pixels P.

The plurality of gate lines GL extend in the first direction X.

The plurality of pixels P are provided between odd-numbered gate lines GL1, GL3, GL5, GL7 and even-numbered gate lines GL2, GL4, GL6, GL8. For example, the plurality of pixels P are provided between the first gate line GL1 and the second gate line GL2, between the third gate line GL3 and the fourth gate line GL4, between the fifth gate line GL5 and the sixth gate line GL6, and between the seventh gate line GL7 and the eighth gate line GL8.

The second gate line GL2 and the third gate line GL3 can be formed adjacent to each other, the fourth gate line GL4 and the fifth gate line GL5 can be formed adjacent to each other, and the sixth gate line GL6 and the seventh gate line GL7 can be formed adjacent to each other.

The plurality of data lines DL extend in a second direction Y intersecting the first direction X.

The first and fifth data lines DL1, DL5 can apply data signals to a first color, for example, a red sub pixel, the second and sixth data lines DL2, DL6 can apply data signals to a second color, for example, a green sub pixel, the third and seventh data lines DL3, DL7 can apply data signals to a third color, for example, a blue sub pixel, and the fourth and eighth data lines DL4, DL8 can apply data signals to a fourth color, for example, a white sub pixel.

Each data line DL1 to DL8 includes two branched sub data lines. For example, the first data line DL1 can include a branched 1-1 sub data line DL11 and a branched 1-2 sub data line DL12, the second data line DL2 can include a branched 2-1 sub data line DL21 and a branched 2-2 sub data line DL22, the third data line DL3 can include a branched 3-1 sub data line DL31 and a branched 3-2 sub data line DL32, and the fourth data line DL4 can include a branched 4-1 sub data line DL41 and a branched 4-2 sub data line DL42.

At this time, the 1-1 sub data line DL11, the 2-1 sub data line DL21, the 3-1 sub data line DL31, the 4-1 sub data line DL41, the 1-2 sub data line DL12, the 2-2 sub data line DL22, the 3-2 sub data line DL32, and the 4-2 sub data line DL42 can be arranged in order in the first direction X, for example, from left to right.

The 1-1 sub data line DL11, the 2-1 sub data line DL21, the 3-1 sub data line DL31, and the 4-1 sub data line DL41 can branch in a first diagonal direction, for example, from the upper right to the lower left, and the 1-2 sub data line DL12, the 2-2 sub data line DL22, the 3-2 sub data line DL32, and the 4-2 sub data line DL42 can branch in a second diagonal direction, for example, from the upper left to the lower right.

The plurality of pixels P can include first to fourth pixels P1, P2, P3, P4, and the first to fourth pixels P1, P2, P3, P4 can be arranged in a repeating manner in the first direction X.

Each of the first to fourth pixels P1, P2, P3, P4 can include three sub pixels, namely, first to third. At this time, the combinations of the three sub pixels provided in each of the first to fourth pixels P1, P2, P3, P4 can be different from each other. For example, the combination of the first to third sub pixels SP1a, SP1b, SP1c of the first pixel P1, the combination of the first to third sub pixels SP2a, SP2b, SP2c of the second pixel P2, the combination of the first to third sub pixels SP3a, SP3b, SP3c of the third pixel P3, and the combination of the first to third sub pixels SP4a, SP4b, SP4c of the fourth pixel P4 can all be different. Accordingly, the first to fourth pixels P1, P2, P3, P4 can emit light of different colors.

For example, the first to third sub pixels SP1a, SP1b, SP1c of the first pixel P1 can be red, green, and blue sub pixels, the first to third sub pixels SP2a, SP2b, SP2c of the second pixel P2 can be white, red, and green sub pixels, the first to third sub pixels SP3a, SP3b, SP3c of the third pixel P3 can be blue, white, and red sub pixels, and the first to third sub pixels SP4a, SP4b, SP4c of the fourth pixel P4 can be green, blue, and white sub pixels.

At this time, between the odd gate lines GL1, GL3, GL5, GL7 and the even gate lines GL2, GL4, GL6, GL8, for example, red, green, blue, and white sub pixels can be arranged in a repeating order in the first direction X, for example, from left to right.

When the sub pixels are repeatedly arranged, the first instance of a first color, for example, a red sub pixel, can be connected to the 1-1 sub data line DL11, the first instance of a second color, for example, a green sub pixel, can be connected to the 2-1 sub data line DL21, the first instance of a third color, for example, a blue sub pixel, can be connected to the 3-1 sub data line DL31, and the first instance of a fourth color, for example, a white sub pixel, can be connected to the 4-1 sub data line DL41. Additionally, a second instance of a first color, for example, a red sub pixel, can be connected to the 1-2 sub data line DL12, a second instance of a second color, for example, a green sub pixel, can be connected to the 2-2sub data line DL22, a second instance of a third color, for example, a blue sub pixel, can be connected to the 3-2sub data line DL32, and a second instance of a fourth color, for example, a white sub pixel, can be connected to the 4-2 sub data line DL42.

For example, in the first row, for example, between the first gate line GL1 and the second gate line GL2, the first to third sub pixels SP1a, SP1b, SP1c of the first pixel P1 and the first sub pixel SP2a of the second pixel P2 can be connected to the first diagonally branched first sub data line DL11, DL21, DL31, DL41 and the first gate line GL1, and the second to third sub pixels SP2b, SP2c of the second pixel P2 and the first to second sub pixels SP3a, SP3b of the third pixel P3 can be connected to the second diagonally branched second sub data line DL12, DL22, DL32, DL42 and the second gate line GL2.

Therefore, as an example, in the case of the first pixel P1 of the first row, all of the first to third sub pixels SP1a, SP1b, SP1c are connected to the first gate line GL1, but in the case of the second pixel P2 of the first row, the first sub pixel SP2a is connected to the first gate line GL1, but the second to third sub pixels SP2b, SP2c can be connected to the second gate line GL2.

The switching thin film transistor is formed near an area where a gate line GL and a data line DL intersect. In the case of the first to third sub pixels SP1a, SP1b, SP1c of the first pixel P1 of the first row, the switching thin film transistor can be formed above near the first gate line GL1. In contrast, in the case of the second pixel P2 of the first row, the switching thin film transistor of the first sub pixel SP2a can be formed above near the first gate line GL1, but the switching thin film transistor of the second to third sub pixels SP2b, SP2c can be formed below near the second gate line GL2.

Meanwhile, in the second direction Y, the same sub pixels may not be arranged in a straight line, but can be arranged in a zigzag structure. For example, between the first gate line GL1 and the second gate line GL2 and between the fifth gate line GL5 and the sixth gate line GL6, the second column can be composed of red sub pixels, the third column can be composed of green sub pixels, the fourth column can be composed of blue sub pixels, and the fifth column can be composed of white sub pixels, whereas between the third gate line GL3 and the fourth gate line GL4 and between the seventh gate line GL7 and the eighth gate line GL8, the second column can be composed of green sub pixels, the third column can be composed of blue sub pixels, the fourth column can be composed of white sub pixels, and the fifth column can be composed of red sub pixels.

For example, in the second column, red sub pixels and green sub pixels can be repeated in the second direction Y, in the third column, green sub pixels and blue sub pixels can be repeated in the second direction Y, in the fourth column, blue sub pixels and white sub pixels can be repeated in the second direction Y, and in the fifth column, white sub pixels and red sub pixels can be repeated in the second direction Y, and accordingly, red, green, blue, and white sub pixels can be arranged in a zigzag structure in the second direction Y.

Between the first gate line GL1 and the second gate line GL2 and between the fifth gate line GL5 and the sixth gate line GL6, for example, the first pixel P1, the second pixel P2, the third pixel P3, and the fourth pixel P4 can be arranged in that order from the second column, whereas between the third gate line GL3 and the fourth gate line GL4 and between the seventh gate line GL7 and the eighth gate line GL8, the fourth pixel P4, the first pixel P1, the second pixel P2, and the third pixel P3 can be arranged in that order from the second column.

According to another embodiment of the present disclosure, since each pixel P1, P2, P3, P4 includes three sub pixels, the size of the pixel can be reduced compared to a case where one pixel includes four sub pixels, and further, since the data line DL includes two branched sub data lines, the number of data drive chips can be reduced.

Meanwhile, among the plurality of pixels P, one pixel includes three sub pixels that display different colors from among red, green, blue, and white, and at this time, a pixel adjacent to one of the pixels can include a sub pixel that displays a different color from the three sub pixels provided in the one pixel. For example, among the three sub pixels provided in a pixel adjacent to one of the pixels, a sub pixel provided most adjacent to the one pixel can display a different color from the three sub pixels provided in the one pixel.

For example, the first pixel P1 of the second row, for example, the first pixel P1 between the third gate line GL3 and the fourth gate line GL4, includes the 1-1 sub pixel SP1a, the 1-2 sub pixel SP1b, and the 1-3 sub pixel SP1c that display red, green, and blue. In this case, the 4-3 sub pixel SP4c of the fourth pixel P4 of the same second row adjacent to the first pixel P1 and the 2-1 sub pixel SP2a of the second pixel P2 can display white. In addition, the 2-1 sub pixel SP2a of the second pixel P2 of the first row above the first pixel P1 and the 2-1 sub pixel SP2a of the second pixel P2 of the third row below the first pixel P1 can display white.

According to another embodiment of the present disclosure, a color that cannot be displayed by three sub pixels provided in one pixel among the plurality of pixels P is displayed by using sub pixels provided in another adjacent pixel among the plurality of pixels P, thereby preventing a decrease in visibility that can occur due to using three sub pixels in one pixel.

Meanwhile, at least one of the common power line, the reference line, and the pixel power line can be additionally formed in the second direction Y between the plurality of data lines DL.

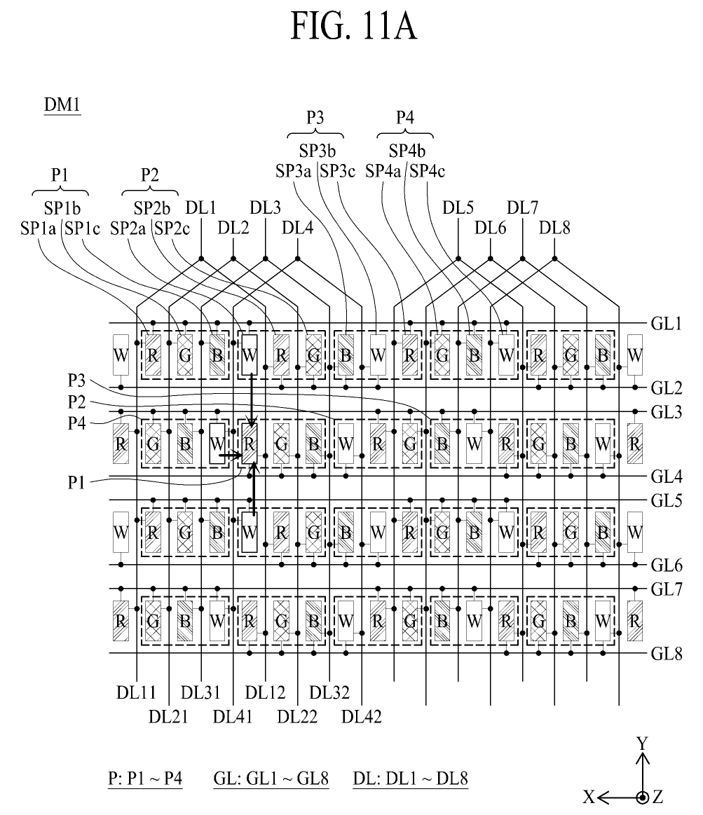

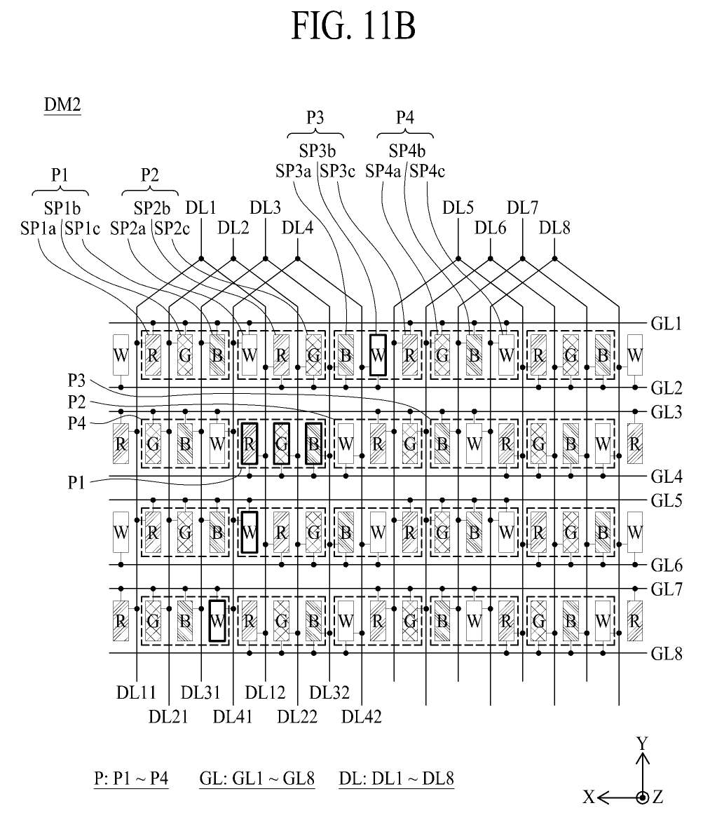

FIG. 11A and FIG. 11B are drawings for explaining the driving mode in the surface image and line image of the display apparatus according to another embodiment of the present disclosure.

As can be seen from FIGS. 11A and 11B, according to another embodiment of the present disclosure, when displaying a line image and a surface image, the driving forms of a plurality of pixels P can be varied to reduce power consumption and improve user visibility. In detail, by driving the plurality of pixels P by rendering, the driving modes of some of the pixels P displaying the surface image and other pixels P displaying the line image can be varied, thereby reducing power consumption in all pixels and improving user visibility.

According to another embodiment of the present disclosure, some of the pixels displaying the surface image among the plurality of pixels P can be driven in a first driving mode DM1 as shown in FIG. 11A, and other pixels displaying the line image among the plurality of pixels P can be driven in a second driving mode DM2 as shown in FIG. 11B.

First, referring to FIG. 11A, the first driving mode DM1 relates to a driving mode in which a color not displayed by the sub pixels of one pixel can be displayed using the sub pixels of another adjacent pixel.

In detail, the first pixel P1 of the second row, for example, the first pixel P1 between the third gate line GL3 and the fourth gate line GL4, is composed of the 1-1 sub pixel SP1a, the 1-2 sub pixel SP1b, and the 1-3 sub pixel SP1c that display red, green, and blue, and does not have a sub pixel that displays white.

In this case, the 4-3 sub pixel SP4c of the fourth pixel P4 in the second row adjacent to the first pixel P1, the 2-1 sub pixel SP2a of the second pixel P2, the 2-1 sub pixel SP2a of the second pixel P2 in the first row adjacent to the first pixel P1, and the 2-1 sub pixel SP2a of the second pixel P2 in the third row adjacent to the first pixel P1 can display white.

Accordingly, when the plurality of pixels P are driven according to the first driving mode DM1 to display a surface image SD, the user can perceive that white light is displayed in the first pixel P1.

Next, referring to FIG. 11B, in the second driving mode DM2, white can be displayed by driving all sub pixels provided in some pixels among the plurality of pixels P that do not include white sub pixels in order to display a line image.

In detail, the first pixel P1 of the second row, for example, the first pixel P1 between the third gate line GL3 and the fourth gate line GL4, is composed of the 1-1 sub pixel SP1a, the 1-2 sub pixel SP1b, and the 1-3 sub pixel SP1c that display red, green, and blue, and does not have a sub pixel that displays white. However, in the second driving mode DM2, white can be displayed by driving all of the 1-1 sub pixel SP1a' to the 1-3 sub pixel SP1c provided in the first pixel P1.

The line images can be perceived by the human eye relatively more sensitively than surface images. Therefore, when displaying the line image, by driving the plurality of pixels P in the second driving mode DM2, white can be directly displayed in the pixels displaying the line image. In this way, by driving the plurality of pixels P in the second driving mode DM2, the user's eyes can perceive the line image smoothly.

According to another embodiment of the present disclosure, by applying the first driving mode DM1 and the second driving mode DM2 in combination according to the line image and the surface image, when the line image is displayed, the user's visibility can be improved, and when the surface image is displayed, the power consumption of each of the plurality of pixels P can be reduced.

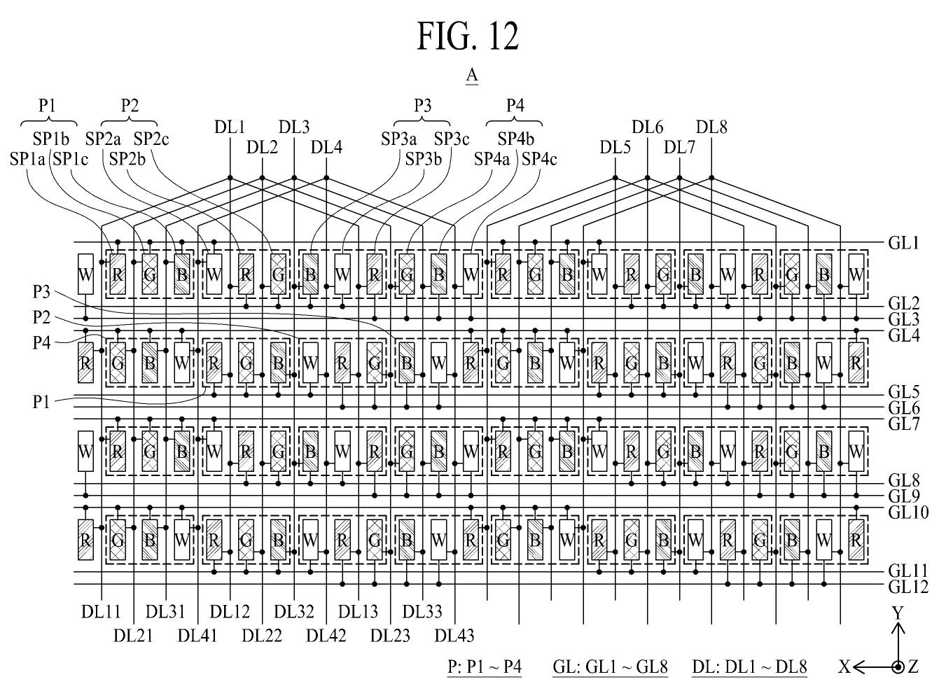

FIG. 12 is a plan view of a display apparatus according to another embodiment of the present disclosure, which is an enlarged view of area A of FIG. 2. FIG. 12 differs from FIG. 10 described above in that the data line DL includes three branched sub data lines. Therefore, the following description will focus on a different configuration.

Referring to FIG. 12, a display apparatus according to another embodiment of the present disclosure comprises a plurality of gate lines GL, a plurality of data lines DL, and a plurality of pixels P.

The plurality of pixels P are provided between the first, fourth, seventh, and tenth gate lines GL1, GL4, GL7, GL10 and the second, fifth, eighth, and eleventh gate lines GL2, GL5, GL8, GL11. The second gate line GL2 and the third gate line GL3, the third gate line GL3 and the fourth gate line GL4, the fifth gate line GL5 and the sixth gate line GL6, the sixth gate line GL6 and the seventh gate line GL7, the eighth gate line GL8 and the ninth gate line GL9, the ninth gate line GL9 and the tenth gate line GL4, and the eleventh gate line GL11 and the twelfth gate line GL12 can be formed adjacent to each other.

Each data line DL1 to DL8 includes three branched sub data lines. For example, the first data line DL1 can include a branched 1-1 sub data line DL11, a 1-2 sub data line DL12, and a 1-3 sub data line DL13, the second data line DL2 can include a branched 2-1 sub data line DL21, a 2-2 sub data line DL22, and a 2-3 sub data line DL23, the third data line DL3 can include a branched 3-1 sub data line DL31, a 3-2 sub data line DL32, and a 3-3 sub data line DL33, and the fourth data line DL4 can include a branched 4-1 sub data line DL41, a 4-2 sub data line DL42, and a 4-3 sub data line DL43.

At this time, the 1-1 sub data line DL11, the 2-1 sub data line DL21, the 3-1 sub data line DL31, the 4-1 sub data line DL41, the 1-2 sub data line DL12, the 2-2 sub data line DL22, the 3-2 sub data line DL32, the 4-2 sub data line DL42, the 1-3 sub data line DL13, the 2-3 sub data line DL23, the 3-3 sub data line DL33, and the 4-3 sub data line DL43 can be arranged in order in the first direction X, for example, from left to right.

The 1-1 sub data line DL11, the 2-1 sub data line DL21, the 3-1 sub data line DL31, and the 4-1 sub data line DL41 can branch in a first diagonal direction, for example, from the upper right to the lower left, and the 1-2 sub data line DL12, the 2-2 sub data line DL22, the 3-2 sub data line DL32, and the 4-2 sub data line DL42 can branch in a second direction Y, and the 1-3 sub data line DL13, the 2-3 sub data line DL23, the 3-3 sub data line DL33, and the 4-3 sub data line DL43 can branch in a second diagonal direction, for example, from the upper left to the lower right, but are not necessarily limited thereto.

Between the first, fourth, seventh, and tenth gate lines GL1, GL4, GL7, GL10 and the second, fifth, eighth, and eleventh gate lines GL2, GL5, GL8, GL11, for example, red, green, blue, and white sub pixels can be arranged in a repeating order in the first direction X, for example, from left to right.

When the above sub pixels are repeatedly arranged, the first instance of the first color, for example, a red sub pixel, can be connected to the 1-1 sub data line DL11, the first instance of the second color, for example, a green sub pixel, can be connected to the 2-1 sub data line DL21, the first instance of the third color, for example, a blue sub pixel, can be connected to the 3-1 sub data line DL31, and the first instance of the fourth color, for example, a white sub pixel, can be connected to the 4-1 sub data line DL41.

Additionally, a second first color, for example, a red sub pixel, can be connected to the 1-2 sub data line DL12, a second instance of the second color, for example, a green sub pixel, can be connected to the 2-2 sub data line DL22, a second instance of the third color, for example, a blue sub pixel, can be connected to the 3-2 sub data line DL32, and a second instance of the fourth color, for example, a white sub pixel, can be connected to the 4-2 sub data line DL42.

Additionally, a third instance of the first color, for example, a red sub pixel, can be connected to the 1-3 sub data line DL13, a third instance of the second color, for example, a green sub pixel, can be connected to the 2-3 sub data line DL23, a third instance of the third color, for example, a blue sub pixel, can be connected to the 3-3 sub data line DL33, and a third instance of the fourth color, for example, a white sub pixel, can be connected to the 4-3 sub data line DL43.

For example, in the first row, for example, between the first gate line GL1 and the second gate line GL2, the first to third sub pixels SP1a, SP1b, SP1c of the first pixel P1 and the first sub pixel SP2a of the second pixel P2 are connected to the first diagonal "sleeve-branched" first sub data lines DL11, DL21, DL31, DL41 and the first gate line GL1.

In the first line, the second to third sub pixels SP2b, SP2c of the second pixel P2 and the first to second sub pixels SP3a, SP3b of the third pixel P3 can be connected to the second sub data lines DL12, DL22, DL32, DL42 and the second gate line GL2 branched in the second direction Y.

In the first line, the third sub pixel SP3c of the third pixel P3 and the first to third sub pixels SP4a, SP4b, SP4c of the fourth pixel P4 can be connected to the third sub data line DL13, DL23, DL33, DL43 and the third gate line GL3 branched in the second diagonal direction.

Therefore, as an example, in the case of the first pixel P1 of the first row, all of the first to third sub pixels SP1a, SP1b, SP1c are connected to the first gate line GL1, but in the case of the second pixel P2 of the first row, the first sub pixel SP2a is connected to the first gate line GL1, but the second to third sub pixels SP2b, SP2c can be connected to the second gate line GL2. In addition, in the case of the third pixel P3 of the first row, the first to second sub pixels SP3a, SP3b are connected to the second gate line GL2, but the third sub pixel SP3c can be connected to the third gate line GL3.

According to another embodiment of the present disclosure, since each pixel P1, P2, P3, P4 includes three sub pixels, the size of the pixel can be reduced compared to a case where one pixel includes four sub pixels, and further, since the data line DL includes three branched sub data lines, the number of data drive chips can be further reduced.

In addition, according to another embodiment of the present disclosure, a color that cannot be displayed by three sub pixels provided in one pixel among the plurality of pixels P is displayed using sub pixels provided in another adjacent pixel among the plurality of pixels P, thereby preventing a decrease in user visibility of pixels provided adjacently among the plurality of pixels P.

Although the embodiments of the present disclosure have been described in more detail with reference to the attached drawings, the present disclosure is not necessarily limited to these embodiments, and various modifications can be implemented without departing from the technical spirit of the present disclosure. Therefore, the embodiments disclosed in the present disclosure are not intended to limit the technical spirit of the present disclosure, but to explain it, and the scope of the technical spirit of the present disclosure is not limited by these embodiments. Therefore, it should be understood that the embodiments described above are illustrative in all aspects and not restrictive. The protection scope of the present disclosure should be interpreted by the claims, and all technical ideas within a scope equivalent thereto should be interpreted as being included in the scope of the rights of the present disclosure.

According to the present disclosure as described above, the following effects are achieved.

According to one or more embodiments of the present disclosure, by combining and arranging sub pixels emitting three colors in one pixel among a plurality of pixels, the area of one of the plurality of transmissive areas is increased, thereby implementing a display apparatus with improved transparency. Accordingly, objects disposed on the back surface of the display apparatus can be more clearly recognized.

According to one or more embodiments of the present disclosure, a display apparatus having high transparency can be implemented while reducing power consumption by driving some of a plurality of pixels in a first driving mode to implement a line image and driving other some of the plurality of pixels in a second driving mode to implement a surface image.

According to one or more embodiments of the present disclosure, since one pixel includes three sub pixels, the size of the pixel can be reduced compared to a case where one pixel includes four sub pixels.

According to one or more embodiments of the present disclosure, the number of data drive chips can be reduced by having the data line include two or three branched sub data lines.

According to one or more embodiments of the present disclosure, a color that cannot be displayed by three sub pixels provided in one pixel among a plurality of pixels is displayed by using sub pixels provided in another adjacent pixel among the plurality of pixels, thereby preventing a decrease in visibility that can occur due to using three sub pixels in one pixel.

The effects of the present disclosure are not limited to the effects mentioned above, and other effects not mentioned will be clearly understood by those skilled in the art from the description below.

What is claimed is:

1. A display apparatus comprising:
a first pixel including three sub pixels configured to display different colors; and
a second pixel adjacent to the first pixel and including three sub pixels configured to display different colors;
wherein one sub pixel among the three sub pixels of the second pixel is configured to display a color different from any of the colors displayed by the three sub pixels of the first pixel.

2. The display apparatus of claim 1,
wherein another one of the three sub pixels of the second pixel is configured to display a same color as one of the three sub pixels of the first pixel, and
a remaining one of the three sub pixels of the second pixel is configured to display a same color as another one of the three sub pixels of the first pixel.

3. The display apparatus of claim 1,
wherein one sub pixel of the second pixel is disposed adjacent to the first pixel.

4. The display apparatus of claim 1 further comprising:
a third pixel adjacent to the first pixel and including three sub pixels configured to display different colors,
wherein one sub pixel among the three sub pixels of the third pixel is configured to display a same color as one sub pixel of the second pixel.

5. The display apparatus of claim 4,
wherein one sub pixel of the third pixel is disposed adjacent to the first pixel.

6. The display apparatus of claim 4,
wherein another one of the three sub pixels of the third pixel is configured to display a same color as one of the three sub pixels of the first pixel and as one of two remaining sub pixels of the second pixel.

7. The display apparatus of claim 6,
wherein a remaining one of the three sub pixels of the third pixel is configured to display a same color as another one of the three sub pixels of the first pixel, and is configured to display a color different from the colors displayed by the three sub pixels of the second pixel.

8. The display apparatus of claim 1,
wherein the three sub pixels of the first pixel and the three sub pixels of the second pixel are arranged in a first direction.

9. The display apparatus of claim 1,
wherein the first pixel includes a 1-1 sub pixel, a 1-2 sub pixel, and a 1-3 sub pixel,
wherein the 1-1 sub pixel and the 1-2 sub pixel are arranged in a first direction, and
wherein the 1-1 sub pixel and the 1-3 sub pixel are arranged in a second direction intersecting the first direction.

10. The display apparatus of claim 1,
wherein a transmissive area is further provided at one side of the first pixel.

11. The display apparatus of claim 1 further comprising:
first to fourth data lines,
wherein each of the first to fourth data lines includes at least two branched sub data lines, and
wherein the at least two branched sub data lines are connected to sub pixels configured to display a same color.

12. The display apparatus of claim 11,
wherein the three sub pixels of the first pixel are connected to one sub data line among the first to third data lines,
wherein one sub pixel of the second pixel is connected to one sub data line of the fourth data line, and
wherein two remaining sub pixels of the second pixel are connected to another respective sub data line of the first data line and the second data line.

13. The display apparatus of claim 11 further comprising:
a first gate line and a second gate line extending in a first direction and spaced apart from each other,
wherein the first pixel and the second pixel are disposed between the first gate line and the second gate line, and
wherein the three sub pixels of the first pixel and one sub pixel of the second pixel are connected to the first gate line, and two remaining sub pixels of the second pixel are connected to the second gate line.

14. The display apparatus of claim 13 further comprising:
a third gate line extending in the first direction adjacent to the second gate line; and
a third pixel adjacent to the second pixel and including three sub pixels configured to display different colors,
wherein two sub pixels of the third pixel are connected to the second gate line, and a remaining one sub pixel of the third pixel is connected to the third gate line.

15. The display apparatus of claim 1,
wherein the three sub pixels of the first pixel are red, green, and blue sub pixels,
wherein one sub pixel of the second pixel is a white sub pixel, and
wherein the first pixel is configured to display white by driving all of the three sub pixels thereof, and
wherein the second pixel is configured to drive at least one sub pixel.

16. A display apparatus comprising:
a first pixel including a red sub pixel, a green sub pixel, and a blue sub pixel;
a second pixel adjacent to the first pixel and including a red sub pixel, a green sub pixel, and a white sub pixel; and
a third pixel adjacent to the first pixel and including a blue sub pixel, a green sub pixel, and a white sub pixel;
wherein the white sub pixel of the second pixel and the white sub pixel of the third pixel are disposed adjacent to the first pixel.

17. The display apparatus of claim 1 further comprising:
a fourth pixel disposed opposite to the first pixel in a first direction and including three sub pixels,
wherein the first to third pixels are arranged in a second direction intersecting the first direction, and
wherein the three sub pixels of the fourth pixel include red, green, and blue sub pixels.

18. The display apparatus of claim 16 further comprising:
a fourth pixel disposed opposite to the first pixel in a first direction and including three sub pixels,
wherein the first to third pixels are arranged in a second direction intersecting the first direction, and
wherein one of the three sub pixels of the fourth pixel is a white sub pixel.

19. The display apparatus of claim 16,
wherein a transmissive area is further provided at one side of each of the first pixel, the second pixel, and the third pixel.

20. The display apparatus of claim 16 further comprising:
a first gate line and a second gate line extending in a first direction and spaced apart from each other, and
first to fourth data lines extending in a second direction intersecting the first direction,
wherein the first pixel and the second pixel are disposed between the first gate line and the second gate line, and
wherein each of the first to fourth data lines includes at least two branched sub data lines.
